(19) United States
(12) Patent Application Publication
(10) Pub. No.: US 2026/0184829 A1
(43) Pub. Date: Jul. 2, 2026

(54) COMPOSITION, REACTIVE FILM, UNDERLAYER FILM, METHOD FOR PRODUCING STRUCTURE CONTAINING PHASE-SEPARATED STRUCTURE, AND POLYMER

(71) Applicant: TOKYO OHKA KOGYO CO., LTD., Kawasaki-shi (JP)

(72) Inventors: Ryutaro Sugawara, Kawasaki-shi (JP); Takehiro Seshimo, Kawasaki-shi (JP); Mitsuo Hagihara, Kawasaki-shi (JP)

(21) Appl. No.: 19/423,723

(22) Filed: Dec. 17, 2025

(30) Foreign Application Priority Data
Dec. 26, 2024 (JP) 2024-230140

(51) Int. Cl. C08F 212/08; C08F 212/14; G03F 7/11

(52) U.S. Cl. CPC C08F 212/08; C08F 212/22; G03F 7/11

(57) ABSTRACT

A composition capable of forming a guide pattern superior in heat resistance, a reactive film, an underlayer film, a method for producing a structure including a phase-separated structure, and a polymer. The composition includes a polymer including a constitutional unit including a structure in which the hydrogen atom of a carboxy group or a hydroxy group is substituted by an acid-dissociating group; and a constitutional unit derived from styrene and/or a styrene derivative, in which the acid-dissociating group is not a tertiary carbon atom-containing aliphatic group, or an acetal protective group.

This application claims priority to Japanese Patent Application No. 2024-230140, filed Dec. 26, 2024, the entire content of which is incorporated herein by reference.

### BACKGROUND OF THE INVENTION

### Field of the Invention

The present invention relates to a composition, a reactive film, an underlayer film, a method for producing a structure containing a phase-separated structure, and a polymer.

### Related Art

In recent years, following further miniaturization of a large-scale integrated circuit (LSI), a technique for processing a finer structure has been demanded. In response to such a demand, a technique has been developed to form a finer structure by utilizing a phase-separated structure formed by self-assembly of block copolymers in which mutually incompatible blocks are bonded to each other (refer, for example, to Patent Document 1).

The block copolymers separate (phase-separate) into micro-regions due to repulsion between the mutually incompatible blocks, then are subjected to heat treatment or the like to form a structure having a regular periodic structure. The periodic structure may be a cylinder (columnar), lamella (plate-like), sphere (spherical), or the like.

To use this phase-separated structure of block copolymers, it is essential that self-assembled nanostructures formed by micro-phase separation be formed only in specific regions and be arranged in a desired direction. To control a position and an orientation of these nanostructures, processes such as graphoepitaxy, which controls phase separation patterns by guiding patterns, and chemical epitaxy, which controls phase separation patterns by differences in a chemical state of a substrate, have been proposed.

As a guide pattern in the chemical epitaxy process, for example, a pattern of a neutralizing film having affinity to any block constituting a block copolymer, a pattern in which a crosslinking polystyrene film having affinity for part of the blocks constituting the block copolymer, and a neutralizing film are repeated, and the like are being used.
Patent Document 1: Japanese Unexamined Patent Application, Publication No. 2008-36491

### SUMMARY OF THE INVENTION

Photolithography is commonly used in the formation of the above-mentioned guide pattern. However, complicated operations are required in photolithography such as the formation of a photosensitive resin film, light exposure, development, etching and removal of the resist film. In addition, light exposure by extreme ultraviolet radiation (EUV) is required for forming a finer guide pattern. However, there is also a problem in EUV exposure in that etching is difficult due to requiring to thin the photosensitive resin film (resist film).

In addition, high-temperature heat treatment is performed upon phase separating a layer containing a block copolymer. For this reason, it is also demanded from the materials of the guide pattern that the chemical state of the guide pattern does not change from the heat treatment (heat resistance).

The present invention has been made in view of the above-mentioned situation, and has an object of providing a composition capable of forming a guide pattern superior in heat resistance by a simple method, a reactive film, an underlayer film, a method for producing a structure including a phase-separated structure, and a polymer.

In order to solve the above-mentioned problems, the present inventors conducted extensive research, a result of which it was found that using a polymer (A) including a constitutional unit (A1) including a structure in which a hydrogen atom in a carboxy group or a hydroxy group has been substituted by a predetermined acid-dissociating group, and a constitutional unit (A2) derived from styrene and/or a styrene derivative, can solve the above-mentioned problems, thereby arriving at completion of the present invention. More specifically, the present invention provides the following.

A first aspect relates to a composition including a polymer (A), in which the polymer (A) includes a constitutional unit (A1) including a structure having a hydrogen atom in a carboxy group or hydroxy group substituted by an acid-dissociating group; and a constitutional unit (A2) derived from styrene and/or a styrene derivative, the acid-dissociating group is not a tertiary carbon atom-containing aliphatic group, or an acetal protective group, the tertiary carbon atom-containing aliphatic group is a group including a tertiary carbon atom, and capable of bonding with a residue from a hydrogen atom being removed from the carboxy group or the hydroxy group, via atomic bonding binding to the tertiary carbon atom, and the acetal protective group is a group capable of forming an acetal structure by bonding with the residue from the hydrogen atom being removed from the carboxy group or the hydroxy group.

A second aspect relates to a reactive film including a polymer (A), and changing in hydrophilicity from action of an acid, in which
the polymer (A) includes a constitutional unit (A1) including a structure having a hydrogen atom in a carboxy group or hydroxy group substituted by an acid-dissociating group; and a constitutional unit (A2) derived from styrene and/or a styrene derivative,
the acid-dissociating group is not a tertiary carbon atom-containing aliphatic group, or an acetal protective group, the tertiary carbon atom-containing aliphatic group is a group including a tertiary carbon atom, and capable of bonding with a residue from a hydrogen atom being from the carboxy group or the hydroxy group being removed, via atomic bonding binding to the tertiary carbon atom, and
the acetal protective group is a group capable of forming an acetal structure by bonding with the residue from the hydrogen atom being removed from the carboxy group or the hydroxy group.

A third aspect relates to an underlayer film for use as a template for phase separation of a block copolymer, the underlayer film being formed by an acid position-selectively acting on the reactive film of the second aspect, the underlayer film including two or more regions having different hydrophilicities from each other.

A fourth aspect relates to a method for producing a structure comprising a phase-separated structure, the method including:
forming the reactive film of the second aspect on a substrate;
coating a photosensitive composition comprising a photo-acid generating agent on the reactive film to form a photosensitive film;
position-selectively exposing the photosensitive film to cause an acid to position-selectively act on the reactive film and form an underlayer film;
removing the photosensitive film;
forming an overlayer film comprising a block copolymer on the underlayer film; and
phase separating the block copolymer of the overlayer film.

A fifth aspect relates to a polymer including: a constitutional unit (A1) including a structure having a hydrogen atom in a carboxy group or a hydroxy group substituted by an acid-dissociating group; and a constitutional unit (A2) derived from styrene and/or a styrene derivative, in which
the acid-dissociating group is not a tertiary carbon atom-containing aliphatic group, or an acetal protective group, the tertiary carbon atom-containing aliphatic group is a group including a tertiary carbon atom, and capable of bonding with a residue from a hydrogen atom being removed from the carboxy group or the hydroxy group, via atomic bonding binding to the tertiary carbon atom, and
the acetal protective group is a group capable of forming an acetal structure by bonding with the residue from the hydrogen atom being removed from the carboxy group or the hydroxy group.

According to the present invention, it is possible to provide a composition capable of forming a guide pattern superior in heat resistance by a simple method, a reactive film, an underlayer film, a method for producing a structure including a phase-separated structure, and a polymer.

### BRIEF DESCRIPTION OF THE DRAWINGS

FIG. 1 is a schematic process diagram for explaining an embodiment of a method for producing a structure containing a phase-separated structure.

### DETAILED DESCRIPTION OF THE INVENTION

Although embodiments of the present invention will be described in detail below, the present invention is not to be limited in any way to the following embodiments, and may be implemented by conducting modifications where appropriate within the scope of the purpose of the present invention.

### <<Composition>>

A composition according to the first aspect includes a polymer (A). Polymer (A) includes a constitutional unit (A1) including a structure in which a hydrogen atom of a carboxy group or a hydroxy group has been substituted by an acid-dissociating group, and a constitutional unit (A2) derived from styrene and/or a styrene derivative. The acid-dissociating group is not a tertiary carbon atom-containing aliphatic group, or an acetal protective group. The tertiary carbon atom-containing aliphatic group is a group including a tertiary carbon atom, and which can bond with the residue from the hydrogen atom being removed from the carboxy group, or hydroxy group, via atomic bonding binding to the tertiary carbon atom. The acetal protective group is a group capable of forming an acetal structure by bonding with the residue from the hydrogen atom being removed from the carboxy group or the hydroxy group.

When forming a photosensitive film containing a photo-acid generating agent on a reactive film formed from the composition according to the first aspect, and position-selectively exposing the photosensitive film, the acid generated from the photo-acid generating agent in an exposed light region acts on an adjacent region of the reactive film. More specifically, by the action of the acid, the acid-dissociating group in the constitutional unit (A1) of the polymer (A) is hydrolyzed, and highly polar carboxy groups or hydroxy groups appear. For this reason, it is possible to form an underlayer film including a high hydrophilicity region (region adjacent to exposed portion of photosensitive film), and a low hydrophilicity region (region adjacent to nonexposed portion of photosensitive film), whereby a guide pattern can be formed by a simple method without performing complex operations such as etching.

In addition, when the acid-dissociating group is a tertiary carbon atom-containing aliphatic group such a tert-butyl group, or an acetal protective group, the acid-dissociating group dissociates even in the nonexposed portion by high-temperature heat treatment, whereby the chemical state of the guide pattern may change. On the other hand, the acid-dissociating group in constitutional unit (A1) of polymer (A) hardly dissociates even with high-temperature heat treatment and thus is superior in heat resistance, due to not being such a functional group.

### <Polymer (A)>

### (Constitutional Unit (A1))

Constitutional unit (A1) includes a structure in which the hydrogen atom in a carboxy group or a hydroxy group is substituted by an acid-dissociating group. The acid-dissociating group is not a tertiary carbon atom-containing aliphatic group, or an acetal protective group. The tertiary carbon atom-containing aliphatic group is a group including a tertiary carbon atom, and which can bond with the residue from the hydrogen atom being removed from the carboxy group, or hydroxy group, via atomic bonding binding to the tertiary carbon atom. The acetal protective group is a group capable of forming an acetal structure by bonding with the residue from the hydrogen atom being removed from the carboxy group or the hydroxy group.

The constitutional unit (A1) preferably includes a structure in which the hydrogen atom of a hydroxy group has been substituted by the acid-dissociating group, from the viewpoint of heat resistance.

As the acid-dissociating group, a group represented by the below Formula (a1-1a), or the below Formula (a1-2a) is preferable.

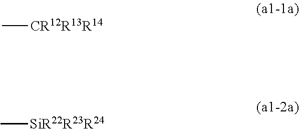

In Formula (a1-1a), R¹² to R¹⁴ are each individually an optionally substituted aromatic group. In Formula (a1-2a), R²² to R²⁴ are each individually an optionally substituted hydrocarbon group.

The aromatic groups as R¹² to R¹⁴ may be aromatic hydrocarbon groups, or may be aromatic heterocyclic groups; however, they are preferably aromatic hydrocarbon groups. The aromatic hydrocarbon group is a group consisting of only an aromatic hydrocarbon ring, or a group in which two or more aromatic hydrocarbon rings are bonded via a single bond. The aromatic hydrocarbon ring may be a single ring, or may be a condensed ring in which two or more rings are condensed. The carbon atom number of the aromatic hydrocarbon group is preferably 6 or more and 20 or less, and more preferably 6 or more and 12 or less. As the aromatic hydrocarbon group, a phenyl group, a naphthyl group, an anthryl group, a phenanthryl group, and a biphenyl group can be exemplified. Thereamong, a phenyl group is preferable.

As the substituent that the aromatic group as R¹² to R¹⁴ may have, an alkyl group, an alkoxy group or the like can be exemplified. Thereamong, an alkyl group is preferable. The carbon atom number of the alkyl group as the substituent is preferably 1 or more and 10 or less, and more preferably 1 or more and 5 or less. The alkyl group may be linear, or may be branched. As the alkyl group, a methyl group, an ethyl group, an n-propyl group, an isopropyl group, an n-butyl group, an isobutyl group, a sec-butyl group, a tert-butyl group or the like can be exemplified. The carbon atom number of the alkoxy group as the substituent is preferably 1 or more and 10 or less, and more preferably 1 or more and 5 or less. The alkyl group in the alkoxy group may be linear, or may be branched. As the alkyl group in the alkoxy group, the groups given by the alkyl groups as the substituent can be exemplified.

The hydrocarbon groups as R²² to R²⁴ may be aliphatic hydrogen groups, or may be aromatic hydrocarbon groups; however, they are preferably aliphatic hydrocarbon groups. The carbon atom number of the aliphatic hydrocarbon group is preferably 1 or more and 10 or less, and more preferably 1 or more and 5 or less. As the aliphatic hydrocarbon group, an alkyl group is preferable. The alkyl group may be linear, or may be branched. As the alkyl group, a methyl group, an ethyl group, an n-propyl group, an isopropyl group, an n-butyl group, an isobutyl group, a sec-butyl group, and a tert-butyl group can be exemplified. The aromatic hydrocarbon group is a group consisting of only an aromatic hydrocarbon ring, or a group in which two or more aromatic hydrocarbon rings are bonded via a single bond. The aromatic hydrocarbon ring may be a single ring, or may be a condensed ring in which two or more rings are condensed. The carbon atom number of the aromatic hydrocarbon group is preferably 6 or more and 20 or less, and more preferably 6 or more and 12 or less. As the aromatic hydrocarbon group, a phenyl group, a naphthyl group, an anthryl group, a phenanthryl group, and a biphenyl group can be exemplified.

As the substituent that the hydrocarbon groups as R²² to R²⁴ may have, an alkyl group, an alkoxy group and the like can be exemplified.

As the constitutional unit (A1), constitutional units represented by the below Formula (a1-1) or Formula (a1-2) are preferable.

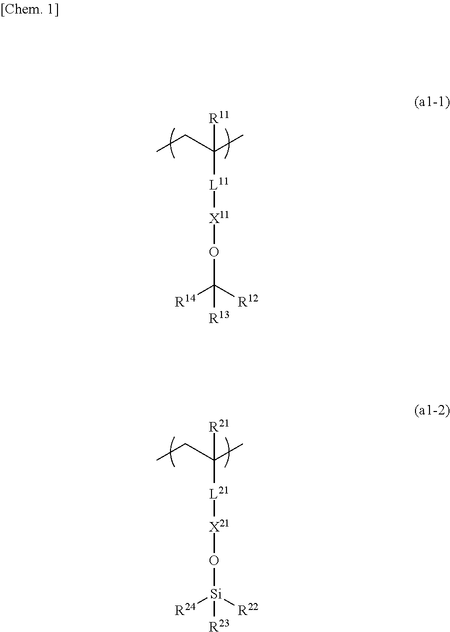

In Formula (a1-1), R¹¹ is a hydrogen atom or a methyl group. L¹¹ is a single bond, or a divalent linking group. X¹¹ is a single bond, or a carbonyl group. R¹² to R¹⁴ are each individually an optionally substituted aromatic group.

In Formula (a1-2), R²¹ is a hydrogen atom or a methyl group. L²¹ is a single bond or a divalent linking group. X²¹ is a single bond, or a carbonyl group. R²² to R²⁴ are each individually an optionally substituted hydrocarbon group.

The divalent linking group as L¹¹ is not particularly limited so long as being a group linking the main chain of polymer (A) with the structure in which the hydrogen atom in a carboxy group or a hydroxy group has been substituted by the acid-dissociating group. The carbon atom number of the divalent linking group as L¹¹ is preferably 1 or more and 10 or less, and more preferably 1 or more and 5 or less.

As the divalent linking group as L¹¹, a group represented by *-L¹²-R¹⁵-** is preferable. L¹² is a divalent linking group including a heteroatom (oxygen atom, nitrogen atom, sulfur atom or the like). R¹⁵ is a divalent aliphatic hydrocarbon group. * is atomic bonding with a carbon atom of the main chain. ** is atomic bonding with X¹¹. Examples of the divalent linking group of L¹² include groups represented by —O—, —C(═O)—O—, —C(═O)—, —O—C(═O)—O—, —C(═O)—NR—, —NR—, —NR—C(═NR)—, —S—, —S(═O)₂—, and —S(═O)₂—O—. In the aforementioned formulas, the R's are each individually a hydrogen atom or a substituent. Examples of the substituent include an alkyl group and an acyl group. It should be noted that the orientation of the bond of the divalent group is not particularly limited unless otherwise specifically noted in the present disclosure. Among these linking groups, a group represented by —C(═O)—O— is preferable.

The carbon atom number of the divalent aliphatic hydrocarbon group as R¹⁵ is preferably 1 or more and 10 or less, and more preferably 1 or more and 5 or less. As the divalent aliphatic hydrocarbon group, an alkylene group is preferable. The alkylene group may be linear, or may be branched. Examples of the alkylene group include a methylene group, an ethane-1,2-diyl group, a propane-1,2-diyl group, a propane-1,3-diyl group, a butane-1,4-diyl group, and a pentane-1, 5-diyl group.

X¹¹ is preferably a single bond from the viewpoint of heat resistance.

R¹² to R¹⁴ in Formula (a1-1) are the same as these groups in Formula (a1-1a).

The divalent linking group as L²¹ is the same as the divalent linking group as L¹¹.

X²¹ is preferably a single bond from the viewpoint of heat resistance.

R²² to R²⁴ in Formula (a1-2) are the same as these groups in Formula (a1-2a).

The ratio of the molar number of constitutional units (A1) relative to the molar number of total constitutional units constituting polymer (A) is preferably 1 mol % or more and 40 mol % or less, more preferably 3 mol % or more and 30 mol % or less, and even more preferably 5 mol % or more and 25 mol % or less. If within the above-mentioned numerical range, the desired effects tend to be obtained.

### (Constitutional Unit (A2))

A constitutional unit (A2) is derived from styrene and/or a styrene derivative.

As the styrene derivative, a compound in which a hydrogen atom bonded to the carbon atom at the x-position of styrene has been substituted by a substituent such as an alkyl group having 1 or more and 10 or less carbon atoms, a compound in which a hydrogen atom of the phenyl group of styrene has been substituted by a substituent such as an alkyl group having 1 or more and 10 or less carbon atoms, an alkoxy group having 1 or more and 10 or less carbon atoms, a hydroxy group, a nitro group, a halogen atom, an acetoxy group, a compound in which two or more hydrogen atoms in the phenyl group of styrene have been substituted and the substituents bond with each other to form a ring, or the like can be exemplified. As the styrene derivative, specifically, x-methylstyrene, 2-methylstyrene, 3-methylstyrene, 4-methylstyrene, 4-tert-butylstyrene, 4-n-octylstyrene, 2,4, 6-trimethylstyrene, 4-methoxystyrene, 4-tert-butoxystyrene, 4-hydroxystyrene, 4-nitrostyrene, 3-nitrostyrene, 4-chlorostyrene, 4-fluorostyrene, 4-acetoxystyrene, 4-chloromethylstyrene, 4-vinylbenzocyclobutene or the like can be exemplified.

As the constitutional unit (A2), a constitutional unit (A2-1) represented by the below Formula (a2-1), and/or a constitutional unit (A2-2) represented by the below Formula (a2-2) are preferable.

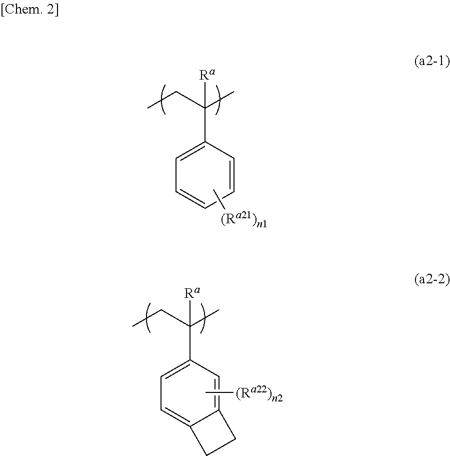

In Formula (a2-1) and Formula (a2-2), R^{a21} and R^{a22} are each individually an alkyl group having 1 or more and 5 or less carbon atoms. n1 is an integer of 0 or more and 5 or less. n2 is an integer of 0 or more and 3 or less. Ra's are each individually a hydrogen atom or an alkyl group having 1 or more and 5 or less carbon atoms.

The alkyl groups of R^{a21}, R^{a22} and Ra may be linear, or may be branched. n1 is preferably an integer of 0 or more and 3 or less, more preferably 0 or 1, and even more preferably 0. n2 is preferably 0 or 1, and more preferably 0.

In a case where it is desired to strengthen the reactive film and the underlayer film, the constitutional unit (A2) preferably includes constitutional unit (A2-2). A crosslinkable benzocyclobutene structure in constitutional unit (A2-2) can crosslink between polymers to improve the strength property.

The ratio of the molar number of constitutional units (A2) relative to the molar number of total constitutional units constituting polymer (A) is preferably 50 mol % or more and 95 mol % or less, more preferably 60 mol % or more and 95 mol % or less, and even more preferably 70 mol % or more and 95 mol % or less. If within the above-mentioned numerical range, the desired effects tend to be obtained.

The ratio of the molar number of constitutional units (A2-1) relative to the molar number of total constitutional units constituting polymer (A) is preferably 50 mol % or more and 95 mol % or less, more preferably 60 mol % or more and 90 mol % or less, and even more preferably 70 mol % or more and 90 mol % or less. If within the above-mentioned numerical range, the desired effects tend to be obtained.

The ratio of the molar number of constitutional units (A2-2) relative to the molar number of total constitutional units constituting polymer (A) is preferably 1 mol % or more and 20 mol % or less, and more preferably 3 mol % or more and 10 mol % or less. If within the above-mentioned numerical range, the desired effects tend to be obtained.

### (Constituent Unit (A3))

Polymer (A) may further include a constituent unit (A3) having a substrate adsorptive group. The substrate adsorptive group is a functional group that can form a bond with a substrate. The bond with the substrate, for example, may be a covalent bond, coordinate bond, hydrogen bond or the like. Examples of the substrate adsorptive group include a hydroxy group, a thiol group, a primary amino group, and a secondary amino group.

As constituent unit (A3), a constituent unit (A 3-1) represented by the below Formula (a3-1) is preferable.

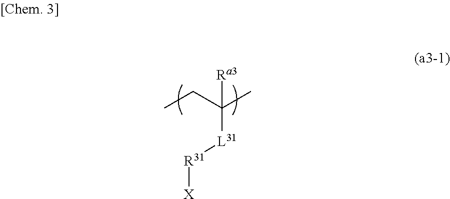

In Formula (a3-1), L³¹ is a single bond or a divalent linking group. R³¹ is a divalent hydrocarbon group. X is a hydroxy group, a thiol group, —NH₂ or ˜NHR³². R³² is an alkyl group. R^{a3} is a hydrogen atom, or an alkyl group having 1 or more and 5 or less carbon atoms.

As L³¹, a divalent linking group is preferable. As the divalent linking group of L³¹, a divalent linking group including a heteroatom such as an oxygen atom, a nitrogen atom, or a sulfur atom is preferable. Examples of the divalent linking group of L³¹ include groups represented by —O—, —C(═O)—O—, —C(═O)—, —O—C(═O)—O—, —C(═O)—NR—, —NR—, —NR—C(═NR)—, —S—, —S(═O)₂—, or —S(═O)₂—O—. In the aforementioned formulas, the R's are each individually a hydrogen atom or substituent. Examples of the substituent include an alkyl group and an acyl group. Among these linking groups, a group represented by —C(═O)—O— is preferable.

The carbon atom number of the divalent aliphatic hydrocarbon group as R³¹ is preferably 1 or more and 10 or less, more preferably 1 or more and 5 or less, and even more preferably 1 or more and 3 or less. As the divalent aliphatic hydrocarbon group, an alkylene group is preferable. The alkylene group may be linear or may be branched; however, it is preferably linear. Examples of the alkylene group include a methylene group, an ethane-1,2-diyl group, a propane-1,2-diyl group, a propane-1,3-diyl group, a butane-1,4-diyl group, and a pentane-1,5-diyl group. A hydroxy group is preferable as X. The carbon atom number of the alkyl group as R^{a3} is preferably 1 or more and 5 or less. As the alkyl group of R^{a3}, a methyl group, an ethyl group, a n-propyl group, an isopropyl group, a n-butyl group, an isobutyl group, a sec-butyl group, and a tert-butyl group can be exemplified. Thereamong, a methyl group is preferable.

In the case of polymer (A) including constitutional unit (A3), the ratio of the molar number of constitutional units (A3) relative to the molar number of total constitutional units constituting polymer (A) is preferably 1 mol % or more and 20 mol % or less, and more preferably 3 mol % or more and 10 mol % or less. If within the above-mentioned numerical range, the desired effects tend to be obtained.

### <Organic Solvent (S)>

The composition according to the first aspect preferably contains an organic solvent (S). The organic solvent (S) is sufficient so long as being an organic solvent which can dissolve each component used, and make a homogenous solution. Any organic solvent selected from among conventionally known organic solvents as solvents for a composition with a resin as a main component can be used.

Examples of the organic solvent include lactones such as γ-butyrolactone; ketones such as acetone, methyl ethyl ketone, cyclohexanone, methyl-n-pentyl ketone, methyl isopentyl ketone and 2-heptanone; polyhydric alcohols such as ethylene glycol, diethylene glycol, propylene glycol and dipropylene glycol; monoacetates of polyhydric alcohols such as ethylene glycol monoacetate, diethylene glycol monoacetate, propylene glycol monoacetate and dipropylene glycol monoacetate; derivatives of polyhydric alcohols, for example, compounds having an ether bond such as monoalkyl ethers of the polyhydric alcohols, monoalkyl ethers of monoacetates of the polyhydric alcohols, monophenyl ethers of the polyhydric alcohols, and monophenyl ethers monoacetates of the polyhydric alcohols (Examples of monoalkyl ethers include monomethyl ether, monoethyl ether, monopropyl ether, and monobutyl ether, or the like.) [among these, propylene glycol monomethyl ether acetate (PGMEA) and propylene glycol monomethyl ether (PGME) are preferred]; cyclic ethers such as dioxane; esters such as methyl lactate, ethyl lactate (E L), methyl acetate, ethyl acetate, butyl acetate, methyl pyruvate, ethyl pyruvate, methyl methoxypropionate, ethyl ethoxypropionate, and esters other than the derivatives of the foregoing polyhydric alcohols; and aromatic organic solvents such as anisole, ethylbenzyl ether, cresylmethyl ether, diphenyl ether, dibenzyl ether, phenetol, butylphenyl ether, ethylbenzene, diethylbenzene, pentylbenzene, isopropylbenzene, toluene, xylene, cymene, and mesitylene. The organic solvent component may be used alone or as a mixed solvent of two or more types. Among them, propylene glycol monomethyl ether acetate (PGMEA), propylene glycol monomethyl ether (PGME), cyclohexanone, and ethyl lactate (E L) are preferable.

The content of the organic solvent contained the composition of the first aspect is not particularly limited. The concentration of the solvent is appropriately set depending upon the coating film thickness so that the concentration of the composition of the first aspect can be applied. The organic solvent is generally used so that the solid content concentration of the composition of the first aspect is in the range of 0.2% by mass or more and 70% by mass or less, and preferably 0.2% by mass or more and 50% by mass or less.

### <Other Components>

To the composition of the first aspect, if desired, compatible additives can further be added as appropriate, such as an additional resin for improving the performance of the underlayer film, a surfactant for improving the coating property, a dissolution inhibitor, a plasticizing agent, a stabilizing agent, a coloring agent, an antihalation agent, dyes, a radiosensitizing agent, a base-proliferating agent and a basic compound, for example.

### <<Polymer>>

The polymer of the fifth aspect includes: constituent units (A1) including a structure in which a hydrogen atom in the carboxy group or hydroxy group has been substituted by the acid-dissociating group, and constituent units (A2) derived from styrene and/or a styrene derivative. The acid-dissociating group is not a tertiary carbon atom-containing aliphatic group, or an acetal protective group. The tertiary carbon atom-containing aliphatic group is a group including a tertiary carbon atom, and bonding with a residue from the hydrogen atom being removed from the carboxy group, or hydroxy group, via atomic bonding binding to the tertiary carbon atom. The acetal protective group is a group capable of forming an acetal structure by bonding with the residue from the hydrogen atom being removed from the carboxy group or hydroxy group.

The polymer of the fifth aspect is the same as polymer (A) contained by the composition of the first aspect.

### <<Method for Producing Structure Having Phase-Separated Structure>>

The method for producing a structure having a phase-separated structure of the fourth aspect includes: forming a reactive film on a substrate (Step (i)); coating a photosensitive composition containing a photo-acid generating agent on the reactive film to form a photosensitive film (Step (ii)); position-selectively exposing the photosensitive film to cause an acid to position-selectively act on the reactive film and form an underlayer film (Step (iii)); removing the photosensitive film (Step (iv)); forming an overlay film containing a block copolymer on the underlayer film (Step (v)); and causing the block copolymer to phase separate in the overlay film (Step (vi)).

### Step (i)

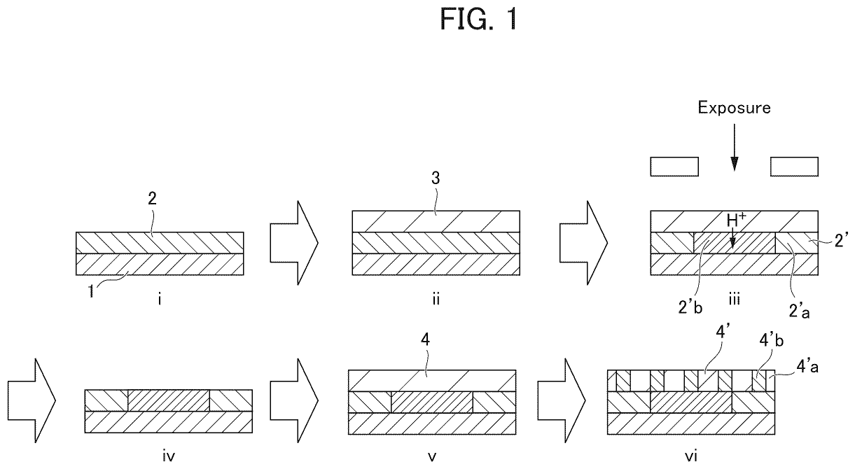

In Step (i), a reactive film 2 is formed on a substrate 1 (refer to (i) in FIG. 1). The reactive film contains polymer (A), and the hydrophilicity changes by the action of the acid. Polymer (A) is the same as polymer (A) contained in the composition of the first aspect.

The reactive film, for example, can be formed by coating the composition of the first aspect on the substrate by a conventional known method such as spin coating to form a coating film, and then drying. The drying method of the coating film is sufficient so long as able to volatilize the organic solvent contained in the composition of the first aspect, and a baking method can be exemplified thereas. At this time, the baking temperature is preferably 80° C. or more and 350° C. or less. The baking time is preferably 30 seconds or more and 600 seconds or less, and more preferably 60 seconds or more and 600 seconds or less. The thickness of the reactive film after drying of the coating film is preferably on the order of 1 nm or more and 150 nm or less, and more preferably on the order of 1 nm or more and 100 nm or less.

The type of substrate is not particularly limited so long as able to coat the composition of the first aspect on the surface thereof. Examples of the substrate include substrates consisting of an inorganic substance such as silicon, a metal (copper, chromium, iron, aluminum, etc.), glass, titanium oxide, silica and mica; substates consisting of an inorganic oxide such as SiO₂; substrates consisting of an inorganic nitride such as SiN; substrates consisting of an inorganic oxide nitride such as SiON; and substrates consisting of an organic substance such as acrylic resin, polystyrene, cellulose, cellulose acetate, and phenolic resin. Thereamong, a silicon substrate (Si substrate) or metal substrate is suitable, a Si substrate or copper substrate (Cu substrate) is more suitable, and a Si substrate is particularly suitable. The size and shape of the substrate are not particularly limited. The substrate does not necessarily have a smooth surface, and substrates of various shapes can be selected as appropriate. For example, a substrate having a curved surface, a flat plate having a surface of uneven shape, and a substrate of a shape such as flaky shape can be exemplified.

A film of an inorganic system and/or organic system may be provided to the surface of the substrate. Examples of the film of an inorganic system include an inorganic antireflection film (inorganic BARC). Examples of the film of an organic system include an organic antireflection film (organic BARC). The film of an inorganic system can be formed by coating an antireflection film composition of an inorganic system such as a silicon-based material onto the substrate, then firing or the like. An organic film can be formed, for example, by applying a material for forming the organic film, in which a resin component or the like to constitute the film is dissolved in an organic solvent, onto a substrate by a spinner or the like, and baking the material under heating conditions of preferably 200° C. or more and 300° C. or less and preferably 30 seconds or more and 300 seconds or less, and more preferably 60 seconds or more and 180 seconds or less. This material for forming an organic film does not necessarily require sensitivity to light or electron beams, unlike a resist film, and may or may not have sensitivity.

Specifically, a resist or a resin generally used in the production of semiconductor elements or liquid crystal display elements can be used. A raw material for forming organic films is preferably a material capable of forming an organic film that can be etched, particularly dry etched, so that a patterned organic film can be formed by etching an organic film using a patterned mask made of a block copolymer formed by processing the overlayer film, and transferring this pattern to the organic film. Among them, a material that can form an organic film that is etchable by oxygen plasma etching or the like is preferable. Such a material for forming an organic film may be a material conventionally used for forming an organic film such as organic BARC. Examples thereof include ARC series manufactured by Nissan Chemical Corporation, AR series manufactured by Rohm & Haas, SWK series manufactured by Tokyo Ohka Kogyo, and the like.

The substrate may be surface treated in advance. By treating the substrate surface, the coating property of the composition of the first aspect improves, whereby polymer (A) will tend to be fixed to the substrate. A conventional known method can be employed as the surface treatment method, and examples thereof include oxygen plasma treatment, ozone oxidation treatment, acid-alkali treatment, and chemical modification treatment.

### Step (ii)

In Step (ii), a photosensitive composition containing a photo-acid generating agent is coated onto the reactive film 2 to form a photosensitive film 3 (refer to (ii) in FIG. 1).

For example, the photosensitive film can be formed by forming coating a photosensitive composition onto the reactive film by a conventional known method such as spin coating to form a coating film, and then drying. The drying method for the coating film is not particularly limited. The drying temperature is preferably 80° C. or more and 350° C. or less. The drying time is preferably 30 seconds or more and 600 seconds or less, and more preferably 60 seconds or more and 600 seconds or less. The thickness of the photosensitive film after drying the coating film is preferably on the order of 1 nm or more and 150 nm or less, and more preferably on the order of 1 nm or more and 100 nm or less.

As the photo-acid generating agent contained in the photosensitive composition is not particularly limited, and a conventional known photo-acid generating agent can be used. More specifically, examples thereof include onium salt-based acid generators such as iodonium salts and sulfonium salts, oxime sulfonate-based acid generators, halogen-containing triazine compounds, diazomethane-based acid generators, nitrobenzyl sulfonate-based acid generators (nitrobenzyl derivatives), iminosulfonate-based acid generators, and disulfone-based acid generators.

The photosensitive composition may contain a resin as a base material component. The resin is not particularly limit so long as being a resin easily removed in Step (iv) later. Examples of such a resin include polymers of a monomer including an unsaturated double bond including hydroxystyrenes (polyhydroxystyrene resins), for example.

The photosensitive composition may contain an organic solvent. An organic solvent that can be used in the composition of the first aspect can be exemplified as the organic solvent.

### Step (iii)

In Step (iii), the photosensitive film 3 is position-selectively exposed to light to cause the acid to position-selectively act on the reactive film, thereby forming an underlayer film 2′ including the two regions 2′a and 2′b having different polarities (refer to (iii) in FIG. 1).

As the method for position-selectively exposing the photosensitive film, for example, a method performing light exposure via a mask can be exemplified. Exposure is performed by irradiating radiation such as ultraviolet rays, ArF excimer laser, KrF excimer laser, F₂ excimer laser, extreme ultraviolet rays (EUV), vacuum ultraviolet rays (VUV), electron beams, X-rays and soft X-rays. Even under a condition of low light exposure, since it is possible to change the polarity of the film surface by exposure, the light exposure is preferably 10 mJ/cm² or more and 300 mJ/cm² or less, more preferably 20 mJ/cm² or more and 200 mJ/cm² or less, and even more preferably 30 mJ/cm² or more and 150 mJ/cm² or less.

In the region of the reactive film adjacent to an exposed light region of the photosensitive film, the acid-dissociating group is hydrolyzed by action of the acid, highly polar carboxy groups and/or hydroxy groups appear, and thus change to a highly hydrophilic region. On the other hand, since the acid does not act on the region of the reactive film adjacent to the unexposed light region of the photosensitive film, the hydrophobicity is maintained. From the above, the underlayer film obtained by causing the acid to position-selectively act on the reactive film has two or more regions having different hydrophilicities from each other, and thus can be used as a template for phase separating the block copolymer.

### <Step (iv)>

In Step (iv), the photosensitive film 3 is removed (refer to (iv) in FIG. 1). The method for removing the photosensitive film 3 is not particularly limited, and a method rinsing the photosensitive film with an organic solvent used in photosensitive compositions can be exemplified.

### Step (v)

In Step (v), an overlayer film 4 containing a block copolymer is formed on the underlayer film 2′ (refer to (v) in FIG. 1). The block copolymer is not particularly limited, and a conventional known block copolymer can be used such as a block copolymer in which blocks having constitutional units containing aromatic groups, and blocks having constitutional units derived from (a-substituted) acrylic esters are bonded (polystyrene-polymethyl methacrylate (PS-PMMA) block copolymer, etc.). The method for forming the overlayer film on the underlayer film is not particularly limited, and a method coating a resin composition for forming a phase-separated structure containing block copolymer and organic solvent on the underlayer film to form a coating film by a conventional known method such as spin coating, for example, and then drying can be exemplified.

### Step (vi)

In Step (vi), the block copolymer of the overlayer film 4 is made to phase separate (refer to (vi) in FIG. 1). The substrate after Step (v) is heated to perform annealing treatment, and the overlayer film 4 is made to phase separate into phase 4′a and phase 4′b, whereby the phase-separated structure 4′ is formed.

### Optional Step

A method for producing a structure having a phase-separated structure may include a step (optional step) other than Steps (i) to (vi). As such an optional step, a step of selectively removing a phase consisting of at least one type of block among the blocks constituting the block copolymer on the overlayer film (hereinafter referred to as Step (vii)) can be exemplified.

### Regarding Step (vii)

In Step (vii), the phase consisting of at least one type of block among the blocks constituting the block copolymer is selectively removed from the overlayer film formed on the underlayer film. A fine pattern (polymer nanostructure) is thereby formed.

As the method for selectively removing a phase consisting of blocks, a method performing oxygen plasma treatment on the overlayer film, a method of performing hydrogen plasma treatment thereon or the like can be exemplified.

As above, the present inventors provide the following (1) to (9).

(1) A composition includes a polymer (A), in which
the polymer (A) includes a constitutional unit (A1) including a structure having a hydrogen atom in a carboxy group or hydroxy group substituted by an acid-dissociating group; and a constitutional unit (A2) derived from styrene and/or a styrene derivative,
the acid-dissociating group is not a tertiary carbon atom-containing aliphatic group, or an acetal protective group,
the tertiary carbon atom-containing aliphatic group is a group including a tertiary carbon atom, and capable of bonding with a residue from a hydrogen atom being removed from the carboxy group or the hydroxy group, via atomic bonding binding to the tertiary carbon atom, and
the acetal protective group is a group capable of forming an acetal structure by bonding with the residue from the hydrogen atom being removed from the carboxy group or the hydroxy group.
   (2) In the composition as described in (1), the constitutional unit (A1) is represented by Formula (a1-1) or Formula (a1-2) below, in which

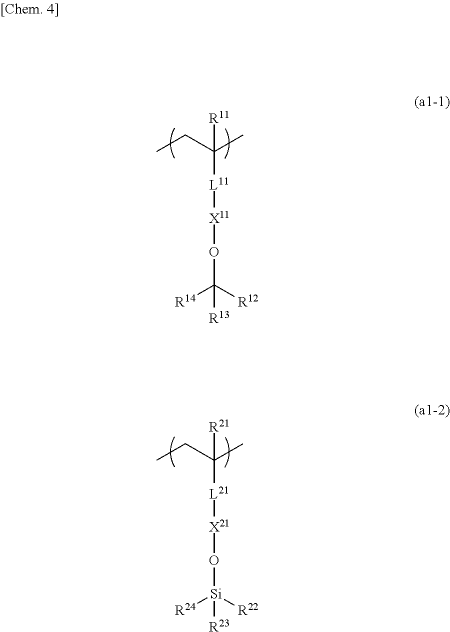

in Formula (a1-1), R¹¹ is a hydrogen atom or a methyl group, L¹¹ is a single bond or a divalent linking group, X¹¹ is a single bond or a carbonyl group, and R¹² to R¹⁴ are each individually an optionally substituted aromatic group, and
in Formula (a1-2), R²¹ is a hydrogen atom or a methyl group, L²¹ is a single bond or a divalent linking group, X²¹ is a single bond or a carbonyl group, and R²² to R²⁴ are each individually an optionally substituted hydrocarbon group.
   (3) In the composition as described in (2), the constitutional unit (A1) is represented by the Formula (a1-1), and
R¹² to R¹⁴ are each individually an optionally substituted phenyl group.
   (4) In the composition as described in (2), the constitutional unit (A1) is represented by the Formula (a1-2), and
R²² to R²⁴ are each individually an alkyl group.
   (5) In the composition as described in any one of (1) to (4), relative to a molar number of total constitutional units constituting the polymer (A),
a ratio of a molar number of the constitutional unit (A1) is 1 mol % or more and 40 mol % or less, and
a ratio of a molar number of the constitutional unit (A2) is 50 mol % or more and 95 mol % or less.
   (6) A reactive film includes a polymer (A), and changes in hydrophilicity from action of an acid, in which
the polymer (A) includes a constitutional unit (A1) including a structure having a hydrogen atom in a carboxy group or hydroxy group substituted by an acid-dissociating group; and a constitutional unit (A2) derived from styrene and/or a styrene derivative,
the acid-dissociating group is not a tertiary carbon atom-containing aliphatic group, or an acetal protective group,
the tertiary carbon atom-containing aliphatic group is a group including a tertiary carbon atom, and capable of bonding with a residue from a hydrogen atom being from the carboxy group or the hydroxy group being removed, via atomic bonding binding to the tertiary carbon atom, and
the acetal protective group is a group capable of forming an acetal structure by bonding with the residue from the hydrogen atom being removed from the carboxy group or the hydroxy group.
   (7) In an underlayer film for use as a template for phase separation of a block copolymer,
the underlayer film is formed by an acid position-selectively acting on the reactive film as described in (6),
   the underlayer film including two or more regions having different hydrophilicities from each other.
   (8) In a method for producing a structure including a phase-separated structure, the method includes:
forming the reactive film as described in (6) on a substrate; coating a photosensitive composition including a photo-acid generating agent on the reactive film to form a photosensitive film;
position-selectively exposing the photosensitive film to cause an acid to position-selectively act on the reactive film and form an underlayer film;
removing the photosensitive film;
forming an overlayer film including a block copolymer on the underlayer film; and
phase separating the block copolymer of the overlayer film.
   (9) A polymer includes: a constitutional unit (A1) including a structure having a hydrogen atom in a carboxy group or a hydroxy group substituted by an acid-dissociating group; and a constitutional unit (A2) derived from styrene and/or a styrene derivative, in which
the acid-dissociating group is not a tertiary carbon atom-containing aliphatic group, or an acetal protective group,
the tertiary carbon atom-containing aliphatic group is a group including a tertiary carbon atom, and capable of bonding with a residue from a hydrogen atom being removed from the carboxy group or the hydroxy group, via atomic bonding binding to the tertiary carbon atom, and
the acetal protective group is a group capable of forming an acetal structure by bonding with the residue from the hydrogen atom being removed from the carboxy group or the hydroxy group.

### EXAMPLES

Hereinafter, the present invention will be described in further detail by way of the Examples; however, the present invention is not to be limited to these examples.

### <Polymer>

Hereinafter, polymers used in the Examples and Comparative Examples will be described.

### Precursor of UL-1, and Synthesis of UL-1

All reactions were performed under a nitrogen atmosphere. An amount of 38.3 g of styrene, 3.03 g of vinylbenzocyclobutene, 12.1 g of hydroxyethyl methacrylate, and 0.269 g of 2,2′-azobis(isobutyrate) dimethyl (V-601) were dissolved in 73.5 g of propylene glycol monomethyl ether acetate (PGMEA). The solution was added dropwise over 2 hours to a 200-mL three-necked flask to which 26 g of PGMEA had been added (external temperature: 87° C.). After dropping completion, the reaction solution was heated and stirred for 3 hours. After cooling the reaction solution to room temperature, it was poured into 1490 g of methanol to perform reprecipitation and purification. The obtained solid was put into 250 g of methanol to perform washing. Reduced-pressure drying was performed at 40° C. to obtain a white solid as a precursor of UL-1.

An amount of 8.15 g of UL-1 precursor, 7.47 g of trityl chloride (TrCl), 2.97 g triethylamine (TEA) and 0.184 g of 4-dimethylaminopyridine (DMAP) were dissolved in 49.8 g of dichloromethane (DCM), and the solution was stirred for 6 hours at room temperature. The reaction solution was poured into 600 g of methanol to cause reprecipitation. The obtained solid was dissolved in 60 g of dichloromethane, and the solution was poured into 600 g of methanol to cause reprecipitation. The same operations were further repeated once to perform purification. The obtained solid was dried at reduced pressure to obtain a white solid as UL-1.

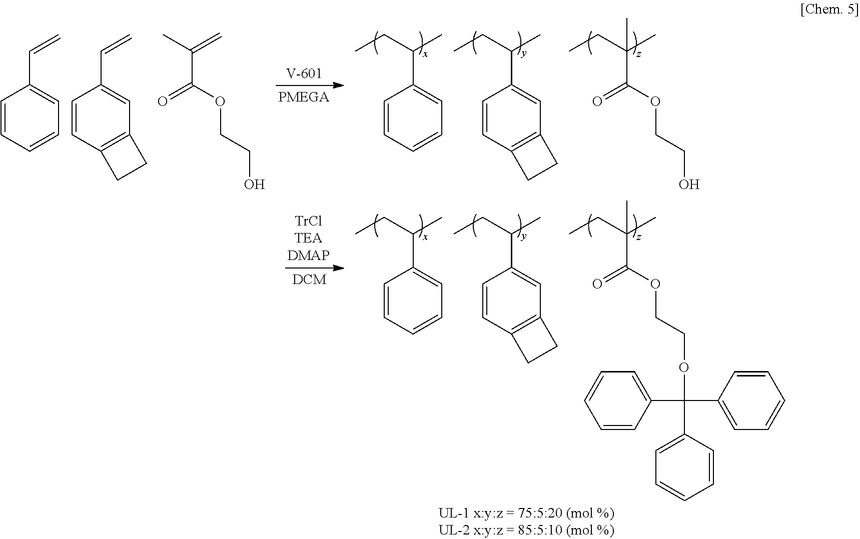

### Synthesis of UL-2

UL-2 was synthesized similarly to the synthesis of UL-1, other than changing the ratio of monomers such as styrene.

### Synthesis of UL-3 and UL-4

UL-3 and UL-4 were respectively synthesized similarly to the synthesis of UL-1 and UL-2, other than changing trityl chloride to 4-methyltrityl chloride.

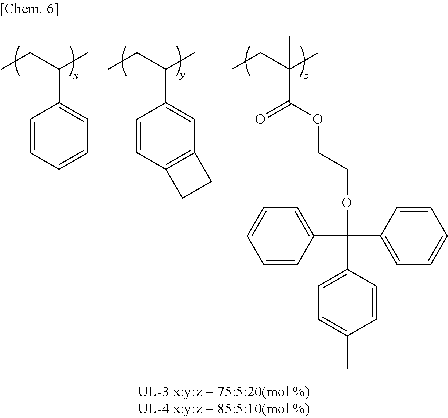

### Synthesis of UL-5 and UL-6

UL-5 and UL-6 were respectively synthesized similarly to the synthesis of UL-1 and UL-2, other than changing trityl chloride to 4-tert-butyltrityl chloride.

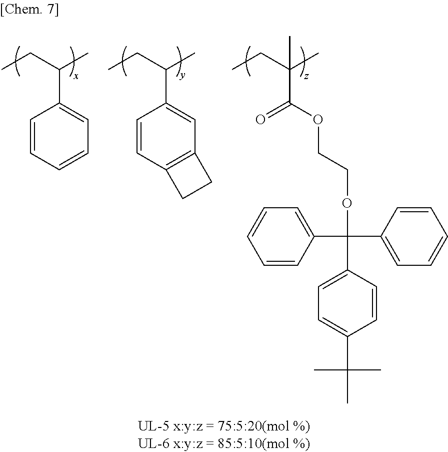

### Synthesis of UL-7 and UL-8

UL-7 and UL-8 were respectively synthesized similarly to the synthesis of UL-1 and UL-2, other than changing trityl chloride to 4,4′-dimethoxytrityl chloride.

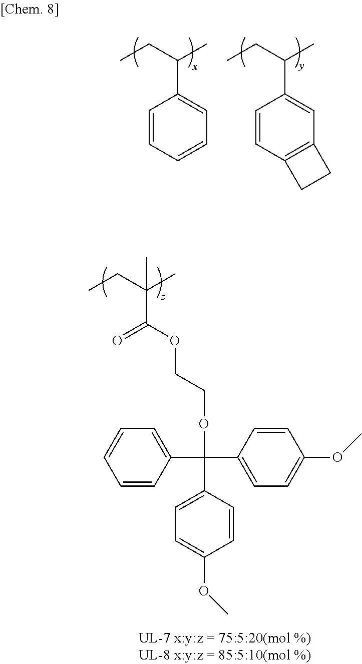

### Synthesis of UL-9 and UL-10

UL-9 and UL-10 were respectively synthesized similarly to the synthesis of UL-1 and UL-2, other than changing trityl chloride to tert-butyldimethylchlorosilane.

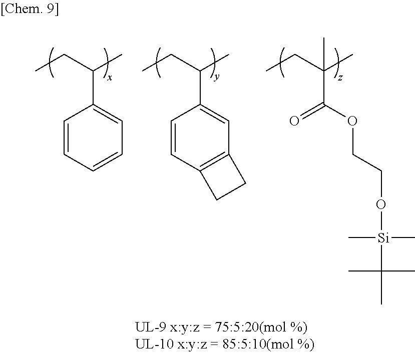

### Monomer of UL-11, and Synthesis of UL-11

All reactions were performed under a nitrogen atmosphere. An amount of 15.0 g of hydroxyethyl methacrylate, 30.5 g of trityl chloride (TrCl), 17.5 of triethylamine (TEA), and 1.41 g of 4-dimethylaminopyridine (DMAP) were dissolved in 204 g of dichloromethane (DCM), and the solution was stirred for 16 hours at room temperature. An amount of 400 g of hexane was added to the reaction solution, and a liquid separation operation with 200 g of water was performed three times. The organic layer was dried at reduced pressure to obtain the monomer of UL-11.

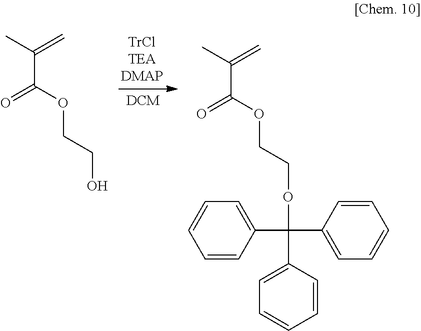

An amount of 38.3 g of styrene, 3.00 g of hydroxyethyl methacrylate, 18.0 g of monomer of UL-11, and 0.269 g of 2,2′-azobis(isobutyrate) dimethyl (V-601) were dissolved in 73.5 g of propylene glycol monomethyl ether acetate (PGMEA). The solution was added dropwise over 2 hours to a 200-mL three-necked flask to which 26 g of PGMEA had been added (external temperature: 87° C.). After dropping completion, the reaction solution was heated and stirred for 3 hours. After cooling the reaction solution to room temperature, it was poured into 1490 g of methanol to perform reprecipitation and purification. The obtained solid was put into 250 g of methanol to perform washing. Reduced-pressure drying was performed at 40° C. to obtain a white solid as a precursor of UL-11.

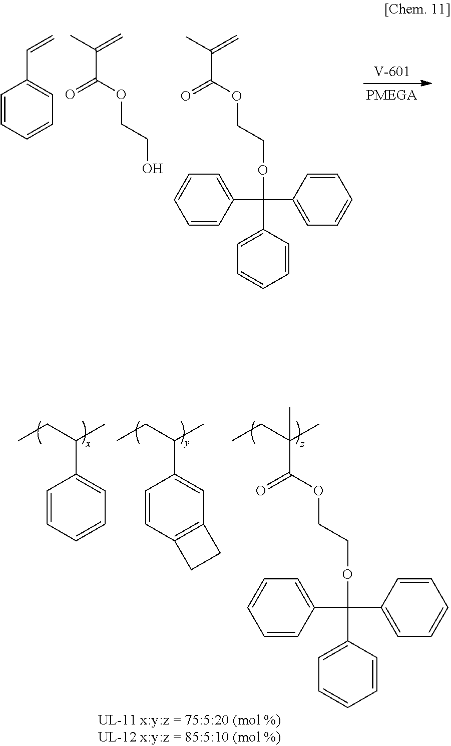

### Synthesis of UL-12

UL-12 was synthesized similarly to the synthesis of UL-11, other than changing the ratio of monomers such as styrene.

### Synthesis of UL-13 and UL-14

UL-13 and UL-14 were respectively synthesized similarly to the synthesis of UL-11 and UL-12, other than changing trityl chloride to 4-methyltrityl chloride.

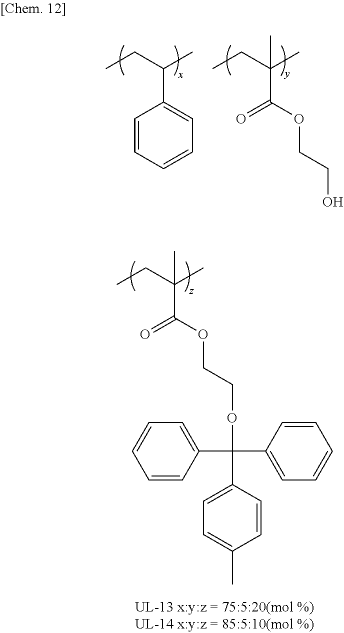

### Synthesis of UL-15 and UL-16

UL-15 and UL-16 were respectively synthesized similarly to the synthesis of UL-11 and UL-12, other than changing trityl chloride to 4-tert-butyltrityl chloride.

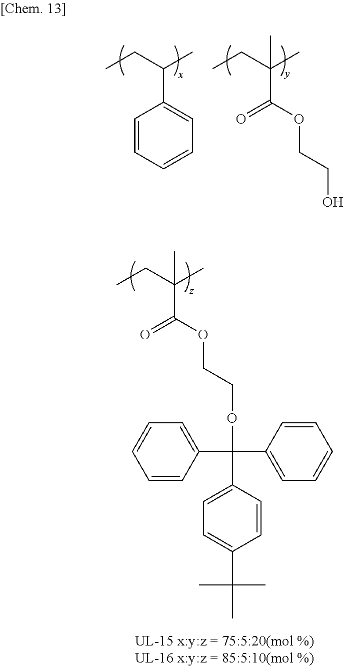

### Synthesis of UL-17 and UL-18

UL-17 and UL-18 were respectively synthesized similarly to the synthesis of UL-11 and UL-12, other than changing trityl chloride to 4,4′-dimethoxytrityl chloride.

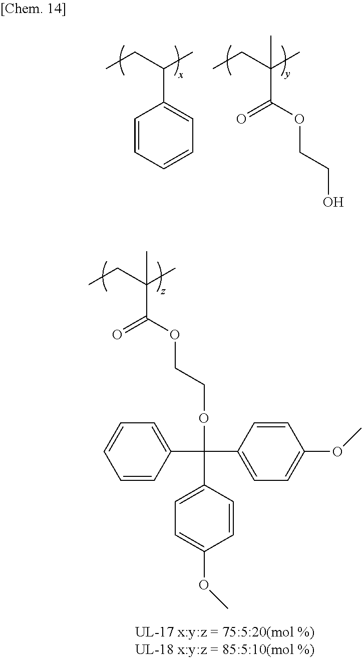

### Synthesis of UL-19 and UL-20

UL-19 and UL-20 were respectively synthesized similarly to the synthesis of UL-11 and UL-12, other than changing trityl chloride to tert-butyldimethylchlorosilane.

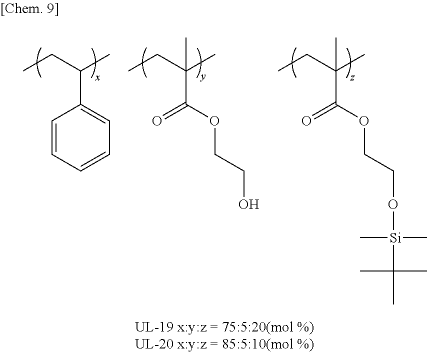

### (Precursor of UL-21, and Synthesis of UL-21)

All reactions were performed under a nitrogen atmosphere. An amount of 38.3 g of styrene, 3.03 g of vinylbenzocyclobutene, 4.00 g of methacrylic acid, and 0.269 g of 2,2′-azobis(isobutyrate) dimethyl (V-601) were dissolved in 73.5 g of propylene glycol monomethyl ether acetate (PGMEA). The solution was added dropwise over 2 hours to a 200-mL three-necked flask to which 26 g of PGMEA had been added (external temperature: 87° C.). After dropping completion, the reaction solution was heated and stirred for 3 hours. After cooling the reaction solution to room temperature, it was poured into 1490 g of methanol to perform reprecipitation and purification. The obtained solid was put into 250 g of methanol to perform washing. Reduced-pressure drying was performed at 40° C. to obtain a white solid as a precursor of UL-21.

An amount of 8.15 g of the precursor of UL-21, 7.47 g trityl chloride (TrCl), 2.97 g of triethylamine (TEA) and 0.184 g of 4-dimethylaminopyridine (DMAP) were dissolved in 49.8 g of dichloromethane (DCM), and the solution was stirred for 6 hours at room temperature. The reaction solution was poured into 600 g of methanol to cause reprecipitation. The obtained solid was dissolved in 60 g of dichloromethane, and the solution was poured into 600 g of methanol to cause reprecipitation. The same operations were further repeated once to perform purification. The obtained solid was dried at reduced pressure to obtain a white solid as UL-21.

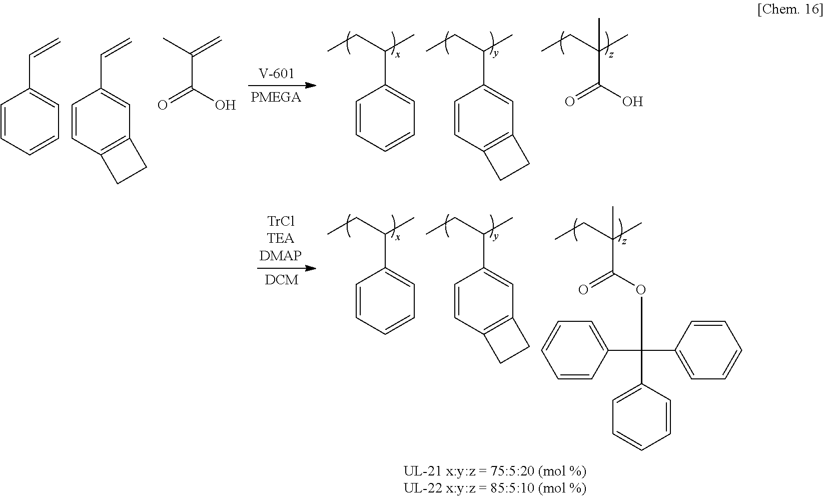

### Synthesis of UL-22

UL-22 was synthesized similarly to the synthesis of UL-21, other than changing the ratio of monomers such as styrene.

### Monomer of UL-23, and Synthesis of UL-23

All reactions were performed under a nitrogen atmosphere. An amount of 9.92 g of methacrylic acid, 30.5 g of trityl chloride (TrCl), 17.5 g of triethylamine (TEA), and 1.41 g of 4-dimethylaminopyridine (DMAP) were dissolved in 204 g of dichloromethane (DCM), and the solution was stirred for 16 hours at room temperature. An amount of 400 g of hexane was added to the reaction solution, and a liquid separation operation with 200 g of water was performed three times. The organic layer was dried at reduced pressure to obtain the monomer of UL-23.

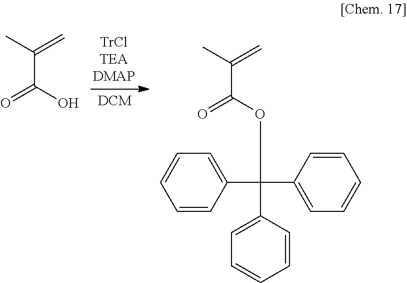

An amount of 38.3 g of styrene, 3.00 g of hydroxyethyl methacrylate, 15.0 g of the monomer of UL-23, and 0.269 g of 2,2′-azobis(isobutyrate) dimethyl (V-601) were dissolved in 73.5 g of propylene glycol monomethyl ether acetate (PGMEA). The solution was added dropwise over 2 hours to a 200-mL three-necked flask to which 26 g of PGMEA had been added (external temperature: 87° C.). After dropping completion, the reaction solution was heated and stirred for 3 hours. After cooling the reaction solution to room temperature, it was poured into 1490 g of methanol to perform reprecipitation and purification. The obtained solid was put into 250 g of methanol to perform washing. Reduced-pressure drying was performed at 40° C. to obtain a white solid as a precursor of UL-23.

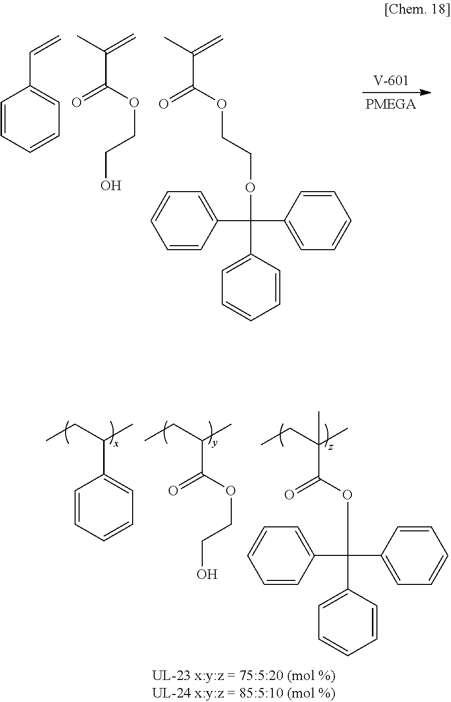

### Synthesis of UL-24

UL-24 was synthesized similarly to the synthesis of UL-23, other than changing the ratio of monomers such as styrene.

UL-25: Random copolymer represented by below formula (x:y:z=77:2:21 (mol %)).

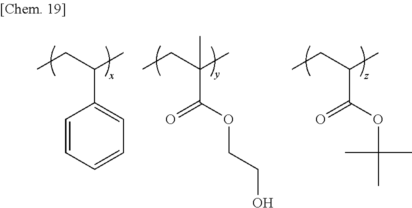

### <Preparation of Composition>

A polymer listed in Table 1 or Table 2 was mixed with propylene glycol monomethyl ether acetate (PGMEA) to prepare each of the compositions of the respective examples (solid content concentration: 1.3% by mass).

### <Heat Resistance Evaluation>

For Examples 1 to 10, 21 and 22, the compositions of the respective examples were coated by spin coating (1500 rpm) onto a silicon substrate so as to make a film thickness of 6 nm, and then baked at 110° C. under an air atmosphere. Furthermore, the substrate was baked for 5 minutes at 250° C. or 310° C. by a hot plate under a nitrogen atmosphere to form the reactive film. For Examples 11 to 20, 23, 24, and Comparative Example 1, the compositions of the respective examples were coated by spin coating (1500 rpm) onto a silicon substrate so as to make a film thickness of 30 nm, and then baked at 200° C. under an air atmosphere. Thereafter, the substrate was rinsed with PGMEA to remove the unreacted polymer. Furthermore, the substrate was baked for 5 minutes at 250° C. or 310° C. by a hot plate under a nitrogen atmosphere to form the reactive film.

Using a Drop Master 700 (manufactured by Kyowa Interface Science Co., Ltd.), a pure water droplet (2.0 μL) was dropped to the surface of the reactive film formed by baking at the respective temperatures, and the contact angle was measured for 1 second each time for a total of 10 times. Measuring at 3 different points on the reactive film, the average value for a total of 30 times was set as the “water contact angle” and is shown in Table 1. A case of the difference between the water contact angle of the reactive film formed by baking at 250° C. and the water contact angle of the reactive film formed by baking at 310° C. being 10° or more was evaluated as “B”, and a case of being less than 10° was evaluated as “A”, and the results are shown in Table 1 as “Heat Resistance”.

TABLE 1

| | |
|---|---|
| Water contact | |
| angle(°) | Heat |

| | Polymer | 250° C. | 310° C. | resistance |
|---|---|---|---|---|
| Comparative | UL-25 | 86 | 60 | B |
| Example 1 | | | | |
| Example 1 | UL-1 | 81 | 81 | A |
| Example 2 | UL-2 | 88 | 88 | A |
| Example 3 | UL-3 | 82 | 82 | A |
| Example 4 | UL-4 | 88 | 88 | A |
| Example 5 | UL-5 | 84 | 84 | A |
| Example 6 | UL-6 | 88 | 88 | A |
| Example 7 | UL-7 | 81 | 78 | A |
| Example 8 | UL-8 | 88 | 87 | A |
| Example 9 | UL-9 | 82 | 76 | A |
| Example 10 | UL-10 | 88 | 84 | A |
| Example 11 | UL-11 | 81 | 81 | A |
| Example 12 | UL-12 | 88 | 88 | A |
| Example 13 | UL-13 | 82 | 82 | A |
| Example 14 | UL-14 | 88 | 88 | A |
| Example 15 | UL-15 | 84 | 84 | A |
| Example 16 | UL-16 | 88 | 88 | A |
| Example 17 | UL-17 | 81 | 78 | A |
| Example 18 | UL-18 | 88 | 87 | A |
| Example 19 | UL-19 | 83 | 76 | A |
| Example 20 | UL-20 | 88 | 84 | A |
| Example 21 | UL-21 | 81 | 81 | A |
| Example 22 | UL-22 | 88 | 88 | A |
| Example 23 | UL-23 | 82 | 82 | A |
| Example 24 | UL-24 | 88 | 88 | A |

As shown in Table 1, in the Examples prepared using polymer (A) having constituent unit (A1) containing a predetermined acid-dissociating group, there was almost no change in the water contact angle even with high-temperature heat treatment; whereas, in the Comparative Examples prepared using a polymer having a constituent unit containing an acid-dissociating group which is a tertiary carbon atom-containing aliphatic group, the water contact angle changed greatly due to the high-temperature heat treatment. In view of this, it was found to have superior heat resistance when using polymer (A) having constituent unit (A1) containing a predetermined acid-dissociating group.

### <Light Exposure Evaluation>

For Examples 1 to 10, 21 and 22, the compositions of the respective examples were coated by spin coating (1500 rpm) onto a silicon substrate so as to make a film thickness of 6 nm, and then baked at 110° C. under an air atmosphere. Furthermore, the substrate was baked for 5 minutes at 250° C. by a hot plate under a nitrogen atmosphere to form the reactive film. For Examples 11 to 20, 23, 24, and Comparative Example 1, the compositions of the respective examples were coated by spin coating (1500 rpm) onto a silicon substrate so as to make a film thickness of 30 nm, and then baked at 200° C. under an air atmosphere. Thereafter, the substrate was rinsed with PGMEA to remove the unreacted polymer. Furthermore, the substrate was baked for 5 minutes at 250° C. by a hot plate under a nitrogen atmosphere to form the reactive film.

A 20% by mass PGMEA solution of photo-acid generating agent represented by the below formula and polyhydroxystyrene was coated by spin coating (1500 rpm) onto the reactive film so as to make a film thickness of 30 nm, and then baked at 110° C. under an air atmosphere to form a photosensitive film.

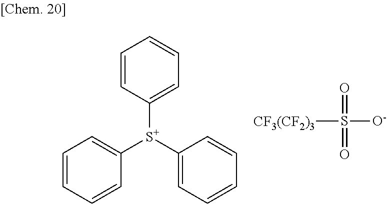

Using a KrF exposure device, a KrF excimer laser (wavelength: 248 nm) was irradiated onto the photosensitive film for an exposure amount of 25 mJ. Therefore, the substrate was post-baked for 1 minute at 110° C., rinsed with a mixed solvent (8:2 (mass ratio)) of propylene glycol monomethyl ether and PGMEA to remove the photosensitive film. The rinsed substrate was baked for 1 minute at 100° C.

Using a Drop Master 700 (manufactured by Kyowa Interface Science Co., Ltd.), a pure water droplet (2.0 μL) was dropped onto the reactive film prior to forming the photosensitive film, or the underlayer film after removing the photosensitive film, and the contact angle was measured for 1 second each time for a total of 10 times. Measuring at 3 different points on the reactive film or underlayer film, the average value for a total of 30 times was set as the “water contact angle” and is shown in Table 2.

TABLE 2

Water contact
angle(°)

| | | Reactive | Underlayer |
|---|---|---|---|
| | Polymer | film | film |
| Example 1 | UL-1 | 81 | 56 |
| Example 2 | UL-2 | 88 | 72 |
| Example 3 | UL-3 | 82 | 57 |
| Example 4 | UL-4 | 88 | 72 |
| Example 5 | UL-5 | 84 | 58 |
| Example 6 | UL-6 | 88 | 71 |
| Example 7 | UL-7 | 81 | 54 |
| Example 8 | UL-8 | 88 | 71 |
| Example 9 | UL-9 | 82 | 57 |
| Example 10 | UL-10 | 88 | 72 |
| Example 11 | UL-11 | 81 | 56 |
| Example 12 | UL-12 | 88 | 72 |
| Example 13 | UL-13 | 82 | 56 |
| Example 14 | UL-14 | 88 | 71 |
| Example 15 | UL-15 | 84 | 58 |
| Example 16 | UL-16 | 88 | 71 |
| Example 17 | UL-17 | 81 | 56 |
| Example 18 | UL-18 | 88 | 72 |
| Example 19 | UL-19 | 83 | 58 |
| Example 20 | UL-20 | 88 | 72 |
| Example 21 | UL-21 | 81 | 50 |
| Example 22 | UL-22 | 88 | 67 |
| Example 23 | UL-23 | 82 | 52 |
| Example 24 | UL-24 | 88 | 66 |

As shown in Table 2, in the Examples prepared using polymer (A) having constituent unit (A1) containing a predetermined acid-dissociating group, the water contact angle greatly changed by exposing the photosensitive film formed on the reactive film. In view of this, it was found that it is possible to form a chemical guide pattern by a simple method without performing complicated operations.

What is claimed is:

1. A composition comprising a polymer (A),
wherein the polymer (A) comprises a constitutional unit (A1) including a structure having a hydrogen atom in a carboxy group or hydroxy group substituted by an acid-dissociating group; and a constitutional unit (A2) derived from styrene and/or a styrene derivative,
wherein the acid-dissociating group is not a tertiary carbon atom-containing aliphatic group, or an acetal protective group,
wherein the tertiary carbon atom-containing aliphatic group is a group including a tertiary carbon atom, and is capable of bonding with a residue from a hydrogen atom being removed from the carboxy group or the hydroxy group, via atomic bonding binding to the tertiary carbon atom, and
wherein the acetal protective group is a group capable of forming an acetal structure by bonding with the residue from the hydrogen atom being removed from the carboxy group or the hydroxy group.

2. The composition according to claim 1, wherein the constitutional unit (A1) is represented by Formula (a1-1) or Formula (a1-2) below, wherein 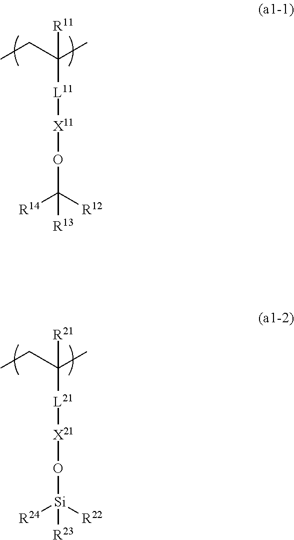
in Formula (a1-1), R¹¹ is a hydrogen atom or a methyl group, L¹¹ is a single bond or a divalent linking group, X¹¹ is a single bond or a carbonyl group, and R¹² to R¹⁴ are each individually an optionally substituted aromatic group, and
in Formula (a1-2), R²¹ is a hydrogen atom or a methyl group, L²¹ is a single bond or a divalent linking group, X²¹ is a single bond or a carbonyl group, and R²² to R²⁴ are each individually an optionally substituted hydrocarbon group.

3. The composition according to claim 2, wherein the constitutional unit (A1) is represented by the Formula (a1-1), wherein R¹² to R¹⁴ are each individually an optionally substituted phenyl group.

4. The composition according to claim 2, wherein the constitutional unit (A1) is represented by the Formula (a1-2), wherein R²² to R²⁴ are each individually an alkyl group.

5. The composition according to claim 1, wherein,
relative to a molar number of total constitutional units constituting the polymer (A),
a ratio of a molar number of the constitutional unit (A1) is 1 mol % or more and 40 mol % or less, and
a ratio of a molar number of the constitutional unit (A2) is 50 mol % or more and 95 mol % or less.

6. A reactive film comprising a polymer (A), and
changing in hydrophilicity from action of an acid, wherein the polymer (A) comprises a constitutional unit (A1) including a structure having a hydrogen atom in a carboxy group or hydroxy group substituted by an acid-dissociating group; and a constitutional unit (A2) derived from styrene and/or a styrene derivative,
wherein the acid-dissociating group is not a tertiary carbon atom-containing aliphatic group, or an acetal protective group,
wherein the tertiary carbon atom-containing aliphatic group is a group including a tertiary carbon atom, and is capable of bonding with a residue from a hydrogen atom being from the carboxy group or the hydroxy group being removed, via atomic bonding binding to the tertiary carbon atom, and
wherein the acetal protective group is a group capable of forming an acetal structure by bonding with the residue from the hydrogen atom being removed from the carboxy group or the hydroxy group.

7. An underlayer film for use as a template for phase separation of a block copolymer,
wherein the underlayer film is formed by an acid position-selectively acting on the reactive film according to claim 6,
and the underlayer film comprises two or more regions having different hydrophilicities from each other.

8. A method for producing a structure comprising a phase-separated structure, the method comprising:
forming the reactive film according to claim 6 on a substrate;
coating a photosensitive composition comprising a photo-acid generating agent on the reactive film to form a photosensitive film;
position-selectively exposing the photosensitive film to cause an acid to position-selectively act on the reactive film and form an underlayer film;
removing the photosensitive film;
forming an overlayer film comprising a block copolymer on the underlayer film; and
phase separating the block copolymer of the overlayer film.

9. A polymer comprising:
a constitutional unit (A1) including a structure having a hydrogen atom in a carboxy group or a hydroxy group substituted by an acid-dissociating group; and
a constitutional unit (A2) derived from styrene and/or a styrene derivative,
wherein the acid-dissociating group is not a tertiary carbon atom-containing aliphatic group, or an acetal protective group,
wherein the tertiary carbon atom-containing aliphatic group is a group including a tertiary carbon atom, and is capable of bonding with a residue from a hydrogen atom being removed from the carboxy group or the hydroxy group, via atomic bonding binding to the tertiary carbon atom, and
wherein the acetal protective group is a group capable of forming an acetal structure by bonding with the residue from the hydrogen atom being removed from the carboxy group or the hydroxy group.
